(19) United States
(12) Patent Application Publication
(10) Pub. No.: US 2023/0207305 A1
(43) Pub. Date: Jun. 29, 2023

(54) RESIDUE-FREE REMOVAL OF STIMULUS RESPONSIVE POLYMERS FROM SUBSTRATES

(71) Applicant: Lam Research Corporation, Fremont, CA (US)

(72) Inventors: Stephen M. SIRARD, Austin, TX (US); Gregory BLACHUT, Campbell, CA (US); Diane HYMES, San Jose, CA (US)

(21) Appl. No.: 17/998,479

(22) PCT Filed: May 10, 2021
(86) PCT No.: PCT/US2021/031594

§ 371 Date: Nov. 10, 2022

Related U.S. Application Data
(60) Provisional application No. 63/023,651, filed on May 12, 2020.

(51) Int. Cl. H01L 21/02; H01J 37/32; B08B 7/00; B08B 7/04

(52) U.S. Cl. CPC H01L 21/02057; H01J 37/32357; H01J 37/32422; B08B 7/0035; B08B 7/0071; B08B 7/04; B08B 2220/04

(57) ABSTRACT

Removing stimulus responsive polymers (SRPs) includes exposure to high energy metastable species, generated in a noble gas plasma, at an elevated temperature. The metastable species have sufficient energies and lifetimes to scission bonds on the polymer or other residues. At temperatures greater than the ceiling temperature of the SRP, there is a strong thermodynamic driving force to revert to volatile monomers once bond scissioning has occurred. The metastable species are not chemically reactive and do not appreciably affect the underlying surface. The high energy metastable species are effective at removing residues that remain after exposure to other stimuli such as heat.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

During semiconductor fabrication, many surfaces are sensitive to airborne molecular contaminants (AMCs) in the surrounding environment. Queue time can lead to exposure to the AMCs and unwanted interactions such as oxidation, corrosion, and halogenation. Solutions include storing partially fabricated semiconductor substrates in nitrogen (N₂)-filled storage cassettes or rooms and using integrated tools that support multiple processes without breaking the vacuum on the substrates. These solutions are difficult and expensive to implement and pose safety and reliability concerns.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect of the disclosure relates to a method of removing a stimuli responsive polymer (SRP) that includes exposure to high energy metastable species, generated from a noble gas plasma, at an elevated temperature. The metastable species have sufficient energies and lifetimes to scission bonds on the polymer or other residues. At temperatures greater than the ceiling temperature of the SRP, there is a strong thermodynamic driving force to revert to volatile monomers once bond scissioning has occurred. The metastable species are not chemically reactive and do not appreciably affect the underlying surface. The metastable species from the noble gas plasma are effective at removing residues that remain after exposure to other stimuli such as heat.

One aspect of the disclosure relates to a method including exposing a substrate having a stimulus responsive polymer (SRP) thereon to a stimulus effective to de-polymerize the SRP and remove the de-polymerized SRP from the substrate; and exposing the substrate to metastable atoms generated from a noble gas plasma, the noble gas being one or more of helium (He), neon (Ne), argon (Ar), krypton (Kr), and xenon (Xe), to remove residue from the substrate.

In some embodiments, the SRP includes a poly(phthalaldehyde) or a derivative thereof as a homopolymer or as one of the polymers of a copolymer. In some embodiments, exposing the substrate to a stimulus includes heating the substrate to a first temperature that is above a ceiling temperature of the SRP. In some such embodiments, the plasma is ignited once the substrate reaches the first temperature.

In some embodiments, most of the SRP is removed before exposing the substrate to the metastable atoms. In some embodiments, the substrate is exposed to the metastable atoms before most of the SRP is removed. In some embodiments, the plasma pressure is between about 10 mTorr to 10 Torr. In some embodiments, the plasma pressure is between about 100 mTorr and 1 Torr. In some embodiments, the SRP is provided between high aspect ratio (HAR) structures. In some embodiments, the SRP is provided as a protective coating on substrate. In some embodiments, the plasma is generated in an inductively coupled plasma (ICP) source. In some such embodiments, the ICP source is separated from the substrate by a showerhead or other filter. In some embodiments, the plasma is generated in capacitively coupled plasma (CCP) source. Any other type of plasma source may be used. In some embodiments, exposing the substrate to a stimulus and exposing the substrate to the metastable atoms are performed in the same chamber.

Another aspect of the disclosure relates to a method including: exposing a substrate to species from a plasma generated from a noble gas to remove residue from a stimulus responsive polymer removal process.

### BRIEF DESCRIPTION OF DRAWINGS

FIGS. 1A and 1B are flow diagrams showing certain operations in examples semiconductor fabrication processes that use stimulus response polymers (SRPs).

FIG. 2 shows a method of removing SRPs according to certain embodiments.

FIG. 3 shows an example of a chamber that may be used to remove SRPs according to certain embodiments.

FIG. 4 is a schematic showing the experimental set-ups for the SRP removal and control substrates.

FIGS. 5A-5C are charts showing the effects of plasma pressure, substrate temperature, and RF power during the plasma operation, respectively, on SRP residue.

FIGS. 6A-6C show the effects of plasma pressure, substrate temperature, and RF power during the plasma operation, respectively, on surface modification of silicon control substrates.

FIG. 7 is a functional block diagram of an example of a substrate processing system including multiple substrate processing tools and a storage buffer according to the present disclosure.

### DETAILED DESCRIPTION

Stimuli responsive polymers (SRPs) may be used in semiconductor fabrication processes for surface protection and queue-time extension. Low ceiling temperature SRPs can be spontaneously removed when exposed to stimuli such as mildly elevated temperatures or acidic vapors, avoiding aggressive wet or dry removal chemistries that may harm the substrate surface. These SRPs can also be used for sacrificial bracing of high aspect ratio (HAR) structures.

As indicated above, in many embodiments, the SRPs are low ceiling temperature (Tₐ) polymers. T_{c} is the equilibrium temperature between a polymer and its monomers. As used herein, the term low T_{c} refers to T_{c} values below a removal temperature. In some embodiments, the T_{c} is below room temperature, such that the polymers are thermodynamically unstable at room temperature. Instead, the low T_{c} polymer is kinetically trapped to allow prolonged storage at room temperature. In some examples, the stable storage period is on the order of months or years. Low T_{c} polymers will rapidly de-polymerize to its monomer constituents if an end-group or main chain bond is broken. Thus, the polymer de-polymerizes in response to stimuli such as ultraviolet (UV) light, heat, or an acidic/basic catalyst. The monomer products are volatile and leave or can be easily removed from the surface and chamber.

While in some embodiments, the T_{c} is below room temperature, in the context of semiconductor processing, low T_{c} may also refer to ceiling temperatures that are higher than room temperature. For example, removal temperatures of up to 400° C. may be used, meaning that the ceiling temperature is below 400° C.

In the methods described herein, removing SRPs includes exposure to high energy metastable species, generated in a noble gas plasma, at an elevated temperature. The metastable species have sufficient energies and lifetimes to scission bonds on the polymer or other residues. At temperatures greater than the ceiling temperature, there is a strong thermodynamic driving force to revert to volatile monomers once bond scissioning has occurred. The metastable species are not chemically reactive and do not appreciably affect the underlying surface. The metastable species are effective at removing residue that remains after exposure to other stimuli such as heat. This residue may be some SRP that remains polymerized or cross-linked and/or carbonized shards that is detectable by ellipsometry. While most of the SRP can be removed by the stimuli described above, this residue can be difficult to fully remove by those methods. Without being bound by a particular theory, the metastables may remove residues by re-initiating chain scissioning that may have stopped prematurely due to side product formation, by breaking down char that may have formed during the depolymerization process, and by aiding monomer desorption.

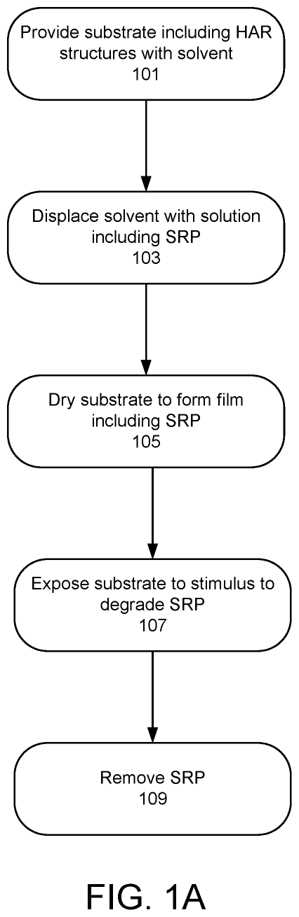

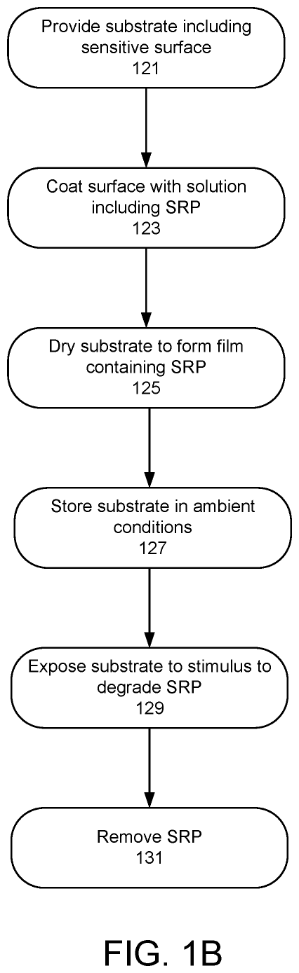

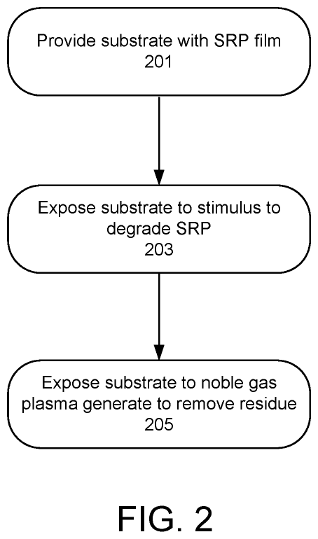

Examples of processes that involve the use of sacrificial SRPs are described below with reference to FIGS. 1A and 1B, with further details of the removal process provided with reference to FIGS. 2-6C. Turning to FIG. 1A, an example of a method for bracing HAR structures using an SRP is shown. First at an operation 101, a substrate including HAR structures with a solvent is provided. HAR structures are structures having high aspect ratios (ARs), e.g., at least 8, 10, 20, 30, 40, or 80. The substrate may be provided, for example, after a wet etch or cleaning operation and have solvent associated with the prior operation. In some embodiments, the solvent in operation 101 may be a transitional solvent if the prior solvent is not chemically compatible with the SRP solution.

Next in an operation 103, the solvent is displaced with a solution that includes a stimuli responsive polymer (SRP). The substrate is then dried in an operation 105. The SRP precipitates out of solution and fills the HAR structures. A mechanical brace forms in the HAR structures to prevent collapse of the structures due to capillary forces that are generated during solvent drying.

The substrate is then exposed to a stimulus, such as light, heat, or acid that degrades the SRP in an operation 107. Monomers or fragments from the degraded polymer remaining on the substrate can then be further removed from the structure in an operation 109. Exposure to metastable species from a noble gas plasma is performed during operations 107 and/or 109.

SRPs may also be used in the semiconductor fabrication processes for transient protection of a sensitive surface of a substrate. This in turn can extend available queue time between processes. FIG. 1B shows an example of a method for protection of a sensitive surface of a substrate. At operation 121, a substrate including an environmentally sensitive surface is provided. The surface may be a planar surface or include one or more pillars, holes, and trenches, including HAR structures. Examples of substrate surfaces that can be sensitive to environmental queue time effects include silicon, silicon germanium, and germanium structures such as fins and nanowires, metal surfaces including but not limited to titanium, titanium nitride, cobalt, tungsten or molybdenum, and/or other structures and materials.

The surface is then coated with a solution including an SRP in an operation 123. The substrate is then dried in an operation 125, forming a protective coating including SRP on the sensitive substrate. The substrate can then be stored in ambient conditions in an operation 127. When ready for further processing, the substrate is exposed to a stimulus, such as light, heat, or acid that degrades the SRP in an operation 129. Monomers or fragments from the degraded polymer remaining on the substrate can then be removed from the structure in an operation 131. Exposure to a metastable species generated in a noble gas plasma may be performed during operations 129 and/or 131.

FIGS. 1A and 1B are flow diagrams showing certain operations in example semiconductor fabrication processes that use SRPs, though the methods described herein are not limited to particular applications but may be used with any application in which SRPs are removed from any surface.

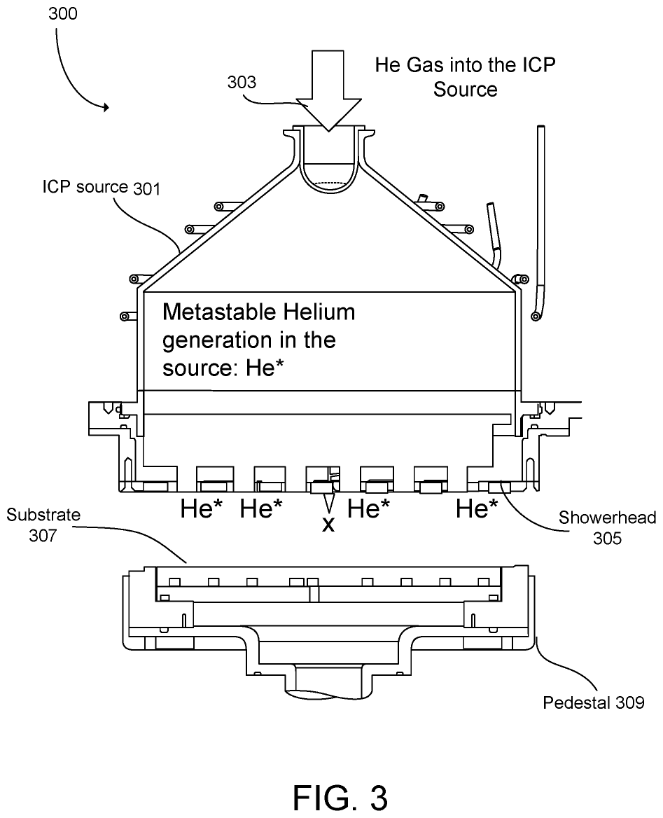

FIG. 2 shows a method of removing SRPs according to certain embodiments. The method begins at an operation 201 in which a substrate having an SRP film thereon is provided to a chamber. The chamber is capable of exposing the substrate to elevated temperatures and metastable species generated from a plasma. An example of a chamber is described below with respect to FIG. 3. Examples of substrates having SRP films are described above with reference to FIGS. 1A and 1B. At 203, the substrate is exposed to a stimulus to degrade the SRP. In many embodiments, this involves heating the substrate to a temperature above the ceiling temperature of the SRP. In alternate embodiments, other stimuli (e.g., UV light) can be used with the appropriate polymer. Exposure to the stimulus degrades into volatile monomers or fragments, which can be pumped out or otherwise removed from the chamber.

In some examples, the SRP is removed using heat at a temperature in a predetermined temperature range from 50° C. to 400° C. In some examples, the SRP is removed using heat at a temperature in a predetermined temperature range from 50° C. to 150° C. In some examples, the sacrificial protective layer is removed using exposure to ultraviolet (UV) light. In some examples, a catalyst is added to the solution forming the polymer. In some examples, a dye is also added to the solution when the photocatalyst is added to control degradation of the polymer. In other examples, an un-catalyzed polymer is deposited and the catalyst is dispensed onto the substrate during removal of the sacrificial protection layer. In some examples, the SRP is removed by exposure to an acidic vapor species. In some examples, the acidic vapor includes hydrogen bromide (HBr) or other acidic vapor. In some examples, when HBr vapor is used, the temperature of the substrate is maintained at a pressure in a range from 5 mT to 5000 mT and a temperature in a range from 0° C. to 100° C. In some examples, the temperature of the substrate is maintained at a pressure in a range from 750 mT to 1500 mT and a temperature in a range from 35° C. to 70° C. In some examples, the temperature of the substrate is maintained at a pressure of 1000 mT and a temperature of 60° C.

At 205, the substrate is exposed to metastables generated from a noble gas plasma. Any of helium (He), neon (Ne), argon (Ar), krypton (Kr), and xenon (Xe) may be used. The substrate is also exposed to a stimulus during 205 as needed to volatilize the residue fragments that are formed by exposure to the metastable species. Typically, though not necessarily, the stimulus in operation 205 is the same as in operation 203, with the substrate continuously exposed. The substrate may be exposed to metastables at any time during stimulus exposure. In some embodiments, operation 203 is first performed, e.g., by heating the substrate to an elevated temperature to remove most of the SRP, then exposing the substrate to the metastables after most of the SRP is removed. In other embodiments, the plasma may be ignited and metastable exposure may occur as soon as the substrate reaches the elevated temperature.

The noble plasmas contain a density of high energy metastable atoms. A metastable atom, also called a metastable, is in an excited state that has a longer lifetime than ordinary excited states. The metastables used herein in the have energies and lifetimes that are sufficient to scission polymer bonds and to remove any monomer or carbonized residue that remain on the surface. Energies above about 5 eV are sufficient to break bonds; the noble gas metastables have energies of about 8 eV and higher. Lifetimes of at least a few seconds are sufficient for this process. And because the noble gases are not chemically reactive, the substrate surface is undamaged. A noble gas plasma may be generated using an inductively coupled plasma (ICP) source as described further below. A capacitively coupled plasma (CCP) source may also be used.

In some embodiments, the gas inlet to the plasma source consists essentially of one or more noble gases. In some embodiments, another gas may be present. If present, the second gas should not modify the substrate.

Processing and plasma source chamber pressure may be used to control the plasma-based removal. Pressure is important to control the density of the metastable atoms. If pressure is too low, the density of metastable atoms may not be high enough to efficiently clean the surface. If the pressure is too high, metastable species may be lost to collisions. Example pressures may range from 10 mTorr to 10 Torr, or 100 mTorr to 700 mTorr.

Substrate temperature and plasma power may also be used to control removal. Temperature is high enough such that it is above the ceiling temperature of the polymer. Higher temperatures aid removal with the maximum temperature limited by the thermal budget of the device or other materials on the substrate. Example temperatures may range from 150° C. to 1000° C. Plasma power is high enough to generate metastable atoms. Example powers may range from 500 W-5000 W, e.g., 2500 W for a 300 mm wafer, and scale linearly with substrate area. Example exposure times may range from 10 seconds-300 seconds.

FIG. 3 shows an example of a chamber 300. The chamber includes or is connected to an ICP source 301 with a gas inlet 303. In the example of FIG. 3, helium gas inlet to the ICP source 301 via gas inlet 303. Metastable He atoms (He*) are generated in the ICP source 301 and pass through a showerhead 305. A substrate 307 on a pedestal 309 in the chamber 300 is exposed to the metastable atoms and is cleaned. The chamber 300 in FIG. 3 is capable of performing both operations 203 and 205. However, in some embodiments, different chambers may be used for these operations. For example, if UV light is used to remove the SRP, a separate UV chamber may be used, or a chamber equipped for both UV and plasma exposure may be used.

In the example of FIG. 3, the substrate is exposed to a downstream or remote plasma, with the showerhead filtering species generated in the ICP source 301 such that the species that make it to the substrate are mostly or all metastable atoms. However, direct plasmas may also be used. For example, a CCP plasma may be generated between a showerhead and a pedestal in a chamber. Direct or indirect ICP sources or direct or indirect CCP sources may be used.

### Examples

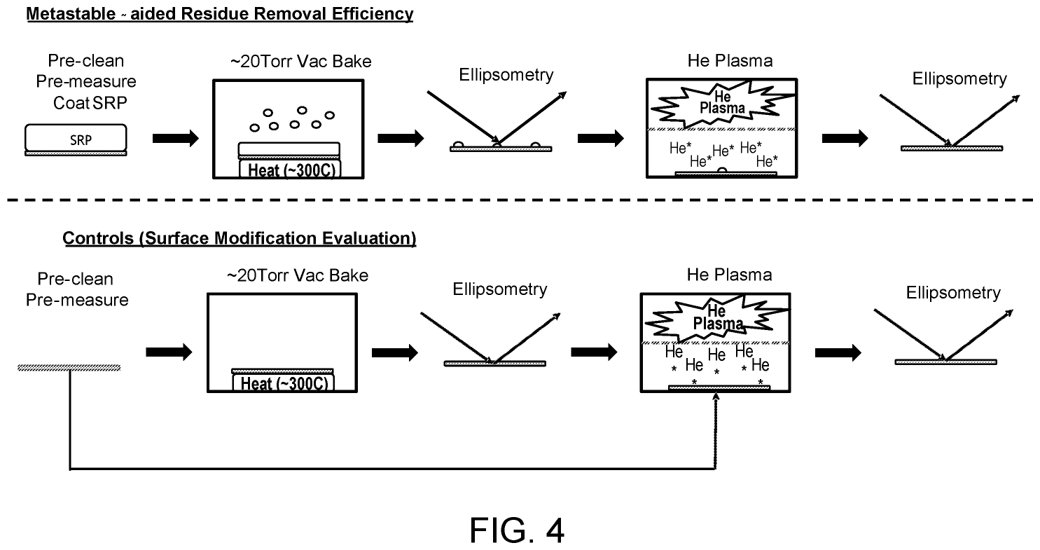

Substrates having SRPs were exposed to a vacuum bake at 20 Torr to remove the SRPs and then exposed to He metastables to remove residues as described above. Control substrates having no SRPs were exposed to the same process to evaluate the surface modification. FIG. 4 is a schematic showing the experimental set-ups for the SRP removal and control substrates. The surfaces were evaluated using ellipsometry after SRP removal and after metastable exposure.

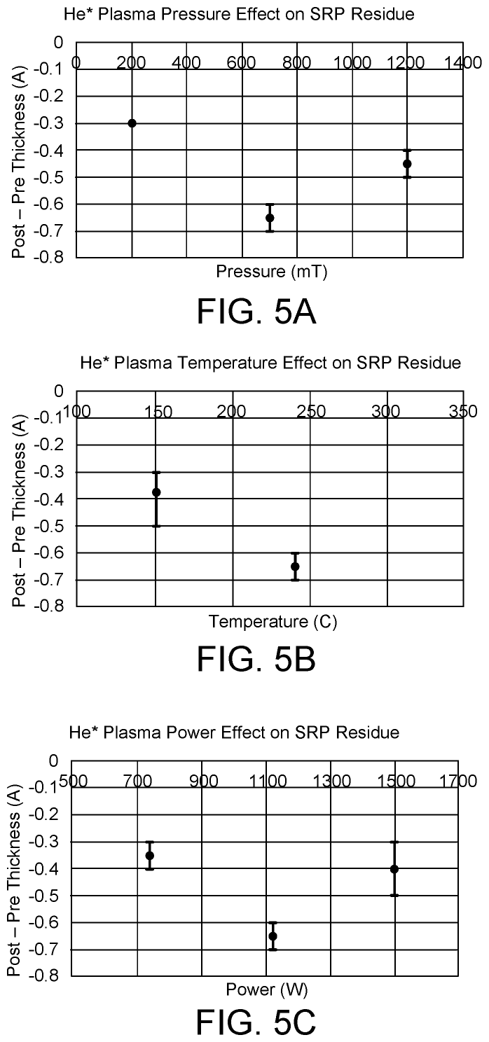

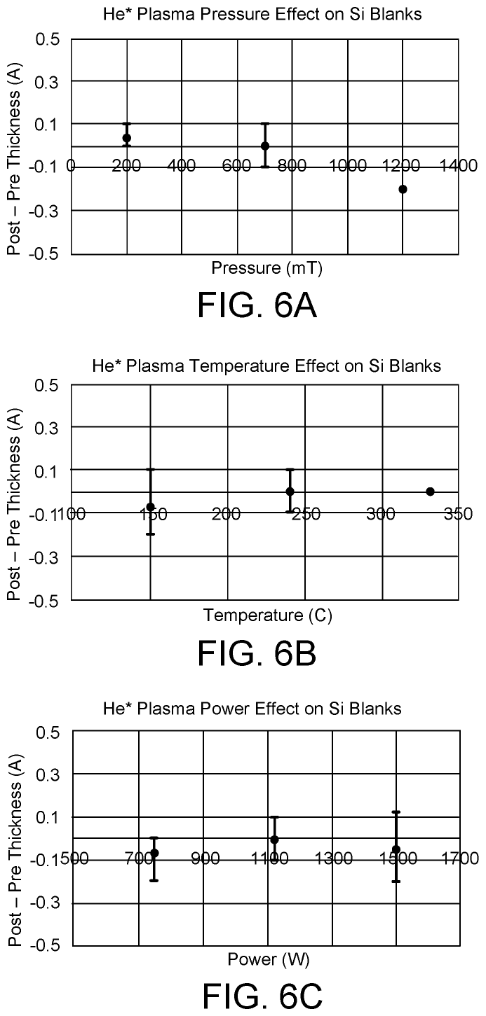

The SRP used was poly(pthalaldehyde-co-ethanal) (PHA-co-EA) (˜46 kDa) dissolved in diglyme. SRP removal was performed at 20 Torr and 330° C. for 5 min with 1600 sccm He/1200 sccm N₂. All silicon wafers were baked at 330° C. to remove adventitious contamination prior to being coated or studied for surface modification. Different metastable plasma conditions were used as shown in FIGS. 5A-5C and 6A-6C. Helium flow was varied with chamber pressure to maintain a constant residence time in the chamber across the different pressures that were used. Exposure time was 60 seconds.

FIGS. 5A-5C show the effects of plasma pressure, substrate temperature, and RF power during the plasma operation, respectively, on SRP residue. FIG. 5A indicates that there may be an optimum pressure (in this example between about 400 mTorr and 900 mTorr) for the reasons described above. Residue removal may improve with increasing temperature; experiments at higher temperatures did not result in useable results due to an unrelated contamination source. The results indicate that at all pressures, temperatures, and powers, exposure to the He metastable atoms results in residue removal.

FIGS. 6A-6C show the effects of plasma pressure, substrate temperature, and RF power during the plasma operation, respectively, on surface modification of the silicon control substrates. Minimal surface modification is observed at all conditions.

### SRPs

Example of SRPs are provided below. However, the methods described herein may be used with any SRPs. In some embodiments, the SRPs are copolymers including poly(aldehydes). In particular embodiments, they may be self-immolative polymers as described in U.S. Patent Publication No. 2018/0155483, which was published on Jun. 7, 2018 and which is hereby incorporated herein by reference in its entirety. Examples of copolymers in that reference include those of Formula I:

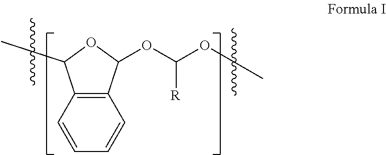

wherein R is substituted or unsubstituted C₁-C₂₀ alkyl, C₁-C₂₀ alkoxyl, C₂-C₂₀ alkenyl, C₂-C₂₀ alkynyl, C₆-C₁₀ heteroaryl, C₃-C₁₀ cycloalkyl, C₃-C₁₀ cycloalkenyl, C₃-C₁₀ heterocycloalkyl, or C₃-C₁₀ heterocycloalkenyl; and, when substituted, R is substituted with C₁-C₂₀ alkyl, C₁-C₂₀ alkoxy, C₂-C₂₀ alkenyl, C₂-C₂₀ alkynyl, C₆-C₁₀ aryl, C₆-C₁₀ heteroaryl, aldehyde, amino, sulfonic acid, sulfinic acid, fluoroacid, phosphonic acid, ether, halide, hydroxy, ketone, nitro, cyano, azido, silyl, sulfonyl, sulfinyl, or thiol.

In particular embodiments, the SRPs are cyclic copolymers of the phthalaldehyde monomer with a second aldehyde such as ethanal, propanal, or butanal. Examples of such copolymers are given in U.S. Patent Publication No. 2018/015548 as Formula II:

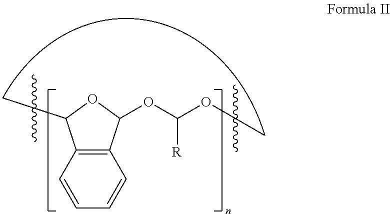

Specific examples in U.S. Patent Publication No. 2018/015548 include copolymers of PHA and one or more of acetaldehyde, propanal, butanal, pentanal, hexanal, heptanal, octanal, nonanal, decanal, undecanal, propenal, butenal, pentenal, hexenal, heptenal, octenal, nonenal, decenal, undecenal, and any combination thereof.

The SRPs may also be any appropriate linear or cyclic copolymer including the pure phthalaldehyde homopolymer. It also may be a homopolymer of poly(phthalaldehyde) derivatives such as poly(4,5-dichlorophthalaldehyde).

### Apparatus

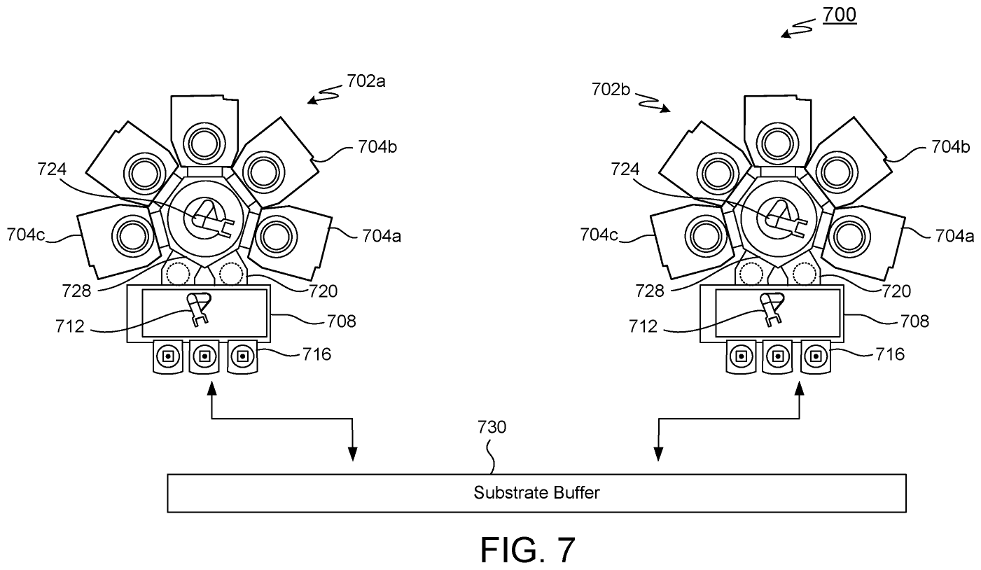

The removal processes described may be implemented in a chamber as described above with reference to FIG. 3, which in some embodiments, may be part of a substrate processing system. The substrate processing system may further include one or more additional substrate processing tools used to process substrates including deposition of SRPs and upstream and downstream processing. Referring now to FIG. 7, a substrate processing system 700 includes one or more substrate processing tools 702 (substrate processing tools 702a and 702b are shown for illustration purposes) and substrate buffer 730 or other substrate storage. Each of the substrate processing tools 702a and 702b includes a plurality of processing chambers 704a, 704b, 704c, etc. (collectively processing chambers 704). For example only, each of the processing chambers 704 may be configured to perform a substrate treatment. In some examples, the substrates may be loaded into one of the processing chambers 704, processed, and then moved to one or more other ones of the processing chambers 704 and/or removed from the substrate processing tool 700 (e.g., if all perform the same treatment).

Substrates to be processed are loaded into the substrate processing tools 702a and 702b via ports of a loading station of an atmosphere-to-vacuum (ATV) transfer module 708. In some examples, the ATV transfer module 708 includes an equipment front end module (EFEM). The substrates are then transferred into one or more of the processing chambers 704. For example, a transfer robot 712 is arranged to transfer substrates from loading stations 716 to load locks 720. A vacuum transfer robot 724 of a vacuum transfer module 728 is arranged to transfer substrates from the load locks 720 to the various processing chambers 704.

After processing in one or more of the substrate processing tools 702a and 702b, the substrates may be transported outside of a vacuum environment. For example, the substrates may be moved to a location for storage (such as the substrate buffer 730). In other examples, the substrates may be moved directly from the substrate processing tool to another substrate processing tool for further processing or from the storage buffer 730 to another substrate processing tool for further processing.

Exposure of the substrate to ambient conditions may cause defects or otherwise adversely impact downstream processing. A sacrificial protective layer including an SRP can be added to the substrate prior to exposure to ambient conditions. In some examples, the sacrificial protective layer is applied in the substrate processing tool prior to transferring the substrate to the substrate buffer for storage or to another substrate processing tool. In other examples, the sacrificial protective layer is applied in another processing chamber (not associated with the substrate processing tool).

Prior to performing another treatment on the substrate, the sacrificial protective layer is removed as described herein. For example, the substrate may be transferred to the substrate processing tool 702a after a period of storage in the storage buffer 730 or after processing in the substrate processing tool 702a. The sacrificial protective layer may be removed in one of the processing chambers in the substrate processing tool 702b, another processing chamber (not associated with the substrate processing tool 702b). In some embodiments, the sacrificial protective layer is removed in a load lock 720.

In some examples, the sacrificial protective layer is applied by a processing chamber in the same substrate processing tool (that performed substrate treatment) prior to exposure to ambient conditions. Since the substrate processing tool operates at vacuum, exposure of the substrate to ambient conditions is prevented. In some examples, the sacrificial layer is deposited after a wet clean process. In this case, oxides and residues may be removed by the wet clean process and the sacrificial layer is deposited in sequence prior to drying the wafer. In some examples, this process is not done under vacuum and is done without any exposure of the dry pristine surface to the ambient. In other examples, the substrate is transported from the substrate processing tool to another processing chamber located outside of the substrate processing tool that adds the sacrificial protective layer. Using this approach limits or reduces the period of exposure of the substrate to ambient conditions. Exposure is limited to a brief period of transport from the substrate processing tool to the processing chamber where the sacrificial protective layer is applied. Storage of the substrate may be performed for longer periods without additional exposure to ambient conditions. Subsequently, the sacrificial protective layer may be removed prior to further processing. In some examples, the sacrificial protective layer is removed in another substrate processing tool under vacuum conditions prior to substrate treatment in processing chambers of the same substrate processing tool. In other examples, the substrate is transported to a processing chamber that removes the sacrificial protective layer and then to the substrate processing tool for further processing. This approach also limits exposure to ambient conditions between the processing chamber and the substrate processing tool or other environment. In one example, the sacrificial protective layer is formed immediately after etch, deposition, or other process by exposing the substrate to a small molecule vapor that condenses on the surface to form a film. This can be performed directly inside the tool in which the etch or deposition occurred (e.g., substrate processing tool 702a) and may occur in the same processing chamber in which the etch or deposition occurred. The substrate is then taken to the next tool for processing (e.g., substrate processing tool 702b). Once the substrate is again no longer exposed to ambient conditions (for example by bringing the substrate under vacuum or an atmosphere purged with an inert gas) vacuum and stimuli as described above are applied to induce the film to degrade and be removed from the substrate. This may take place inside of a processing chamber as described above (e.g., process chamber 704a).

In various embodiments, a system controller is employed to control process conditions during processing including during the SRP removal. The controller will typically include one or more memory devices and one or more processors. A processor may include a CPU or computer, analog and/or digital input/output connections, stepper motor controller boards, etc.

The controller may control all the activities of a removal apparatus. The system controller executes system control software, including sets of instructions for controlling the timing, mixture of gases, chamber pressure, chamber temperature, wafer temperature, wafer chuck or pedestal position, plasma power, and other parameters of a particular process. Other computer programs stored on memory devices associated with the controller may be employed in some embodiments.

Typically, there will be a user interface associated with the controller. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the noble gas flow into the plasma generator, pressure, temperature and other parameters in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, substrate temperature, and plasma power. These parameters are provided to the user in the form of a recipe and may be entered utilizing the user interface.

Signals for monitoring the process may be provided by analog and/or digital input connections of the system controller. The signals for controlling the process are output on the analog and digital output connections of the system.

The system software may be designed or configured in many ways.

For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a PVD chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck. A plasma power program may control plasma power.

Examples of chamber sensors that may be monitored during removal include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically comprises some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
exposing a substrate having a stimulus responsive polymer (SRP) thereon to a stimulus effective to de-polymerize the SRP and remove the de-polymerized SRP from the substrate; and
exposing the substrate to metastable atoms generated from a noble gas plasma, the noble gas being one or more of helium (He), neon (Ne), argon (Ar), krypton (Kr), and xenon (Xe), to remove residue from the substrate.

2. The method of claim 1, wherein the SRP comprises a polyaldehyde or a derivative thereof.

3. The method of claim 1, wherein the SRP comprises a poly(phthalaldehyde) or a derivative thereof as a homopolymer or as one of the polymers of a copolymer.

4. The method of claim 1 wherein exposing the substrate to a stimulus comprises heating the substrate to a first temperature that is above a ceiling temperature of the SRP.

5. The method of claim 4, wherein the plasma is ignited once the substrate reaches the first temperature.

6. The method of claim 1, wherein most of the SRP is removed before exposing the substrate to the metastable atoms.

7. The method of claim 1, wherein substrate is exposed to the metastable atoms before most of the SRP is removed.

8. The method of claim 1, wherein the plasma pressure is between about 10 mTorr to 10 Torr.

9. The method of claim 1, wherein the plasma pressure is between about 100 mTorr and 1 Torr.

10. The method of claim 1, wherein the SRP is provided between high aspect ratio (HAR) structures.

11. The method of claim 1, wherein the SRP is provided as a protective coating on substrate.

12. The method of claim 1, wherein the plasma is generated in an inductively coupled plasma (ICP) source.

13. The method of claim 12, wherein the ICP source is separated from the substrate by a showerhead or other filter.

14. The method of claim 1, wherein the plasma is generated in capacitively coupled plasma (CCP) source.

15. The method of claim 1, wherein exposing the substrate to a stimulus and exposing the substrate to the metastable atoms are performed in the same chamber.

16. A method comprising:
exposing a substrate to species from a plasma generated from a noble gas to remove residue from a stimulus responsive polymer removal process.
